(19) United States
(12) Patent Application Publication
(10) Pub. No.: US 2008/0271912 A1
(43) Pub. Date: Nov. 6, 2008

(54) PRINTED CIRCUIT BOARD AND MANUFACTURING METHOD THEREOF

(75) Inventors: Takahiro Yoshida, Saitama (JP); Takeshi Yoda, Saitama (JP)

Correspondence Address: DITTHAVONG MORI & STEINER, P.C., 918 Prince St., Alexandria, VA, 22314, US

(73) Assignee: TAIYO INK MFG. CO., LTD., Tokyo (JP)

(21) Appl. No.: 12/110,606

(22) Filed: Apr. 28, 2008

(30) Foreign Application Priority Data
Apr. 27, 2007 (JP) 2007-119871
Mar. 17, 2008 (JP) 2008-68373

(51) Int. Cl. H05K 1/00; G03F 7/20

(52) U.S. Cl. 174/250; 430/319

(57) ABSTRACT

Provided is a printed circuit board which can be improved in plating adhesiveness to give high reliability and productivity by reducing development residues in opening portions such as a minute pad formed in a predetermined region of an alkali development type solder resist layer, and a manufacturing method thereof. An alkali development type solder resist layer containing a carboxyl group-containing urethane (meth)acrylate compound as a carboxyl group-containing resin is formed on a substrate surface with a conductor pattern formed thereon, and the alkali development type solder resist layer is exposed in a predetermined opening pattern, developed in a dilute aqueous alkaline solution, washed with water containing 30 to 1,000 ppm of divalent metal ions, and then thermally cured to form an opening portion at a predetermined position of the alkali development type solder resist layer.

### CROSS-REFERENCE TO RELATED APPLICATIONS

The present application claims priority under 35 U.S.C. §119 to Japanese Patent Application No. 2007-119871, filed Apr. 27, 2007, and Japanese Patent Application No. 2008-68373, filed Mar. 17, 2008. The contents of these applications are incorporated herein by reference in their entirety.

### BACKGROUND OF THE INVENTION

1. Field of the Invention

The present invention relates to a printed circuit board and a method of manufacturing the printed circuit board.

2. Discussion of the Background

Because of the recent rapid advance of semiconductor parts, electronic equipment has shown tendencies toward reduced size and weight, higher performance, and multiple functions, followed by the increasingly higher density of printed circuit boards. In response to such higher density, IC packages referred to as QFP (Quad Flatpack Package), SOP (Small Outline Package) and the like have given way to IC packages referred to as BGA (Ball Grid Array), CSP (Chip Scale Package) and the like, which have made their debuts. In such package substrates and printed circuit boards for automobile use, solder resists are used in opening portions such as pads on package substrates connected to semiconductors in order to be gold-plated for improvement in reliability.

Furthermore, core materials to be used in such printed circuit boards and package substrates have been increasingly thinned and, for example, TAB (Tape Automated Bonding), T-BGA (Tape Ball Grid Array), T-CSP (Tape Chip Scale Package), and UT-CSP (Ultra Thin Chip Scale Package) have made their debuts. Such thinner core materials have posed a problem of warpage due to the curing shrinkage of a solder resist. In addition, such core materials applied on tapes require the use of a roll-to-roll method, necessitating a dry film type solder resist from the viewpoint of operability, reliability, film thickness precision, and smoothness. Since such dry film type solder resists are supplied in sheet or roll form, their resin compositions must contain resin components with excellent flexibility and film-formation property due to the characteristics of their resin forms.

An example of such resin components with excellent flexibility and film-formation property is a photosensitive resin provided by reacting a compound containing a polymerizable unsaturated group, a carboxyl group, and at least one hydroxyl group in one molecule, with a terminal isocyanate compound provided by reacting a rubber-like compound or a compound containing at least one carboxyl group and two hydroxyl groups in one molecule, a diol compound, and a polyisocyanate compound. For example, Japanese Patent Laid-Open No. 2003-192760, Japanese Patent Laid-Open No. 2002-162739, Japanese Patent Laid-Open No. 2004-252485 and Japanese Patent Laid-Open No. 2007-71966 disclose such resin. However, there is such a problem that formulation of such resin components with excellent flexibility and film-formation property in solder resists results in reduction in yield and reliability due to deterioration of developability, production of development residues in opening portions such as a minute pad, and deterioration of adhesiveness of gold plating or the like. Accordingly, a decrease in productivity can occur though the residues may be removed by repeating development.

### SUMMARY OF THE INVENTION

According to one aspect, the present invention includes steps of forming an alkali development type solder resist layer containing a carboxyl group-containing urethane (meth)acrylate compound as a carboxyl group-containing resin on a substrate surface with a conductor pattern formed thereon; and of forming an opening portion at a predetermined position of the alkali development type solder resist layer by exposing the alkali development type solder resist layer in a predetermined opening pattern, by developing the layer in a dilute aqueous alkaline solution, by washing the layer with water containing 30 to 1,000 ppm of divalent metal ions, and then by thermally curing the layer.

According to one aspect, the present invention also includes a substrate with a conductor pattern formed thereon, and an alkali development type solder resist layer formed on the substrate and containing a carboxyl group-containing urethane (meth)acrylate compound and divalent metal ions, in which an opening portion is formed at a predetermined position.

In this connection, ppm, which is a unit of metal ion concentration, represents a milligram of metal ions included in one liter of a sample.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a view showing a relationship between calcium ions and a treatment area per liter of wash water when using wash water containing 100 ppm of calcium ions;

FIG. 2 is an electron microscope photograph of a pad portion washed with wash water containing 50 ppm of magnesium ions according to one embodiment of the present invention;

FIG. 3 is an electron microscope photograph of a pad portion washed with wash water containing 10 ppm of magnesium ions according to a comparative example;

FIG. 4 is an electron microscope photograph of a pad portion washed with wash water containing 10,000 ppm of magnesium ions according to a comparative example;

FIG. 5 is an electron microscope photograph of a pad portion washed with wash water containing 115 ppm of strontium ions according to one embodiment of the present invention;

FIG. 6 is an electron microscope photograph of a pad portion washed with wash water containing 12 ppm of strontium ions according to a comparative example;

FIG. 7 is an electron microscope photograph of a pad portion washed with wash water containing 23,000 ppm of strontium ions according to a comparative example;

FIG. 8 is an electron microscope photograph of a pad portion washed with wash water containing 240 ppm of barium ions according to one embodiment of the present invention;

FIG. 9 is an electron microscope photograph of a pad portion washed with wash water containing 12 ppm of barium ions according to a comparative example;

FIG. 10 is an electron microscope photograph of a pad portion washed with wash water containing 24,000 ppm of barium ions according to a comparative example; and

FIG. 11 is an electron microscope photograph of a pad portion washed with wash water containing 5 ppm of aluminum ions according to a comparative example.

### DESCRIPTION OF THE EMBODIMENTS

The embodiments will now be described with reference to the accompanying drawings, wherein like reference numerals designate corresponding or identical elements throughout the various drawings.

The method of manufacturing a printed circuit board according an embodiment of the present invention is suitably used in gold plating a printed circuit board with a difficult-to-develop minute pad portion (having, for example, an opening diameter between 20 and 100 μm) using an alkali development type solder resist.

The method of manufacturing a printed circuit board according to an embodiment of the present invention includes forming an alkali development type solder resist layer containing a carboxyl group-containing urethane (meth)acrylate compound as a carboxyl group-containing resin on a substrate surface with a conductor pattern formed thereon; and forming an opening portion at a predetermined position of the alkali development type solder resist layer by exposing the alkali development type solder resist layer in a predetermined opening pattern, by developing the layer in a dilute aqueous alkaline solution, by washing the layer with water containing 30 to 1,000 ppm of divalent metal ions, and then by thermally curing the layer.

More specifically, the method of manufacturing a printed circuit board according to this embodiment includes the steps of:

1. forming an alkali development type solder resist layer on a substrate surface with a conductor pattern formed thereon;
2. exposure;
3. developing in a dilute aqueous alkaline solution;
4. washing with water containing 30 to 1,000 ppm of divalent metal ions;
5. rinsing the wash water (as needed);
6. drying a substrate (steps 3 to 6 are generally collectively referred to as a development step); and
7. thermal curing.

After completion of these steps, a printed circuit board provided with an alkali development type solder resist layer, in which an opening portion is formed on a predetermined position, is formed on a substrate surface with a conductor pattern formed thereon.

First, an alkali development type solder resist layer described below is formed on a substrate surface with a conductor pattern formed thereon. For the purpose of this step, examples of such a substrate with a conductor pattern formed thereon include a copper-clad laminate substrate for a high frequency circuit which employs, for example, paper phenol, paper epoxy, glass fabric epoxy, glass polyimide, glass fabric/nonwoven fabric epoxy, glass fabric/paper epoxy, synthetic fiber epoxy, or fluorine/polyethylene/PPO/cyanate ester; all grades (e.g., FR-4) of copper-clad laminate substrates, and other substrates with a conductor pattern formed on a polyimide film, PET film, glass substrate, ceramic substrate, wafer board, or the like.

The step of forming an alkali development type solder resist layer on the surface of such a substrate is performed using a liquid alkali development type solder resist or a dry film with the alkali development type solder resist layer.

When using the liquid alkali development type solder resist, it is adjusted with an organic solvent (D-1) described below in viscosity suitable for a coating method, and coated on the entire substrate with a conductor pattern formed thereon by a method such as dip coating, flow coating, roll coating, bar coating, screen printing, and curtain coating. The organic solvent (D-1) included in the alkali development type solder resist is then volatilized (temporarily dried) at a temperature of about 60 to 100° C. Thus, a tack-free alkali development type solder resist layer can be formed.

The dry film with an alkali development type solder resist layer has a carrier film, a solder resist layer provided by drying the carrier film (or a cover film) coated with an alkali development type solder resist, and a cover film which can be stripped off on the solder resist layer.

A polyester film such as PET with a thickness of 10 to 150 μm, a polyimide film, or the like may be used as a carrier film.

An alkali development type solder resist layer is formed by decreasing the viscosity of an alkali development type solder resist with an organic solvent (D-1) so as to allow the resist to be coated on a carrier film or a cover film, and then by uniformly coating the resist with a thickness of, for example, 10 to 150 μm on the carrier film (or the cover film) using a blade coater, lip coater, comma coater, film coater, or the like, before drying.

A polyethylene film, a polypropylene film, or the like may be used as a cover film, which preferably has lower adhesive strength to an alkali development type solder resist layer than that of a carrier film.

When such a dry film with an alkali development type solder resist is used, a cover film is stripped off to arrange an alkali development type solder resist layer on a carrier film onto a substrate with a conductor pattern formed thereon. The alkali development type solder resist layer can be then formed on the substrate with a conductor pattern formed thereon, by lamination with the use of a laminator. In this case, the carrier film may be stripped off before or after exposure. The lamination is performed usually at 60 to 110° C. and 0.4 MPa or higher using a heating laminator. In this case, a vacuum laminator can be used to prevent voids from occurring.

Next, the alkali development type solder resist layer formed in such a manner is exposed in a predetermined opening pattern. In this exposure step, a contact or non-contact exposure machine employing a low-pressure mercury lamp, a medium-pressure mercury lamp, a high-pressure mercury lamp, an ultra-high-pressure mercury lamp, a xenon lamp, or a metal halide lamp is generally used as an irradiation light source of an activity energy line. Furthermore, a laser direct imaging system employing a laser beam may be also used.

The alkali development type solder resist layer exposed in such a manner is developed using a dilute aqueous alkaline solution as a developing solution. In this development step, a dipping method, a shower method, a spray method, or the like may be used, and the spray method is preferably used in consideration of a subsequent water washing step.

Dilute aqueous alkaline solutions containing a monovalent alkali metal salt or ammonium salt such as potassium hydroxide, sodium hydroxide, sodium carbonate, potassium carbonate, sodium phosphate, sodium silicate, ammonia, and amines can be used as a developing solution.

The alkali development type solder resist layer immediately after being developed in such a manner is washed with wash water containing 30 to 1,000 ppm of divalent metal ions.

Examples of divalent metal ions contained in wash water to be used in this water washing step include calcium ions (Ca2+), magnesium ions (Mg2+), strontium ions (Sr2+), barium ions (Ba2+) and the like. Those metal ions which have no adverse effect on the insulating properties of a printed circuit board are preferably used, and calcium ions and magnesium ions are preferred in particular.

Examples of compounds containing these divalent metal ions include, for example, chlorides, hydroxides, sulfates, phosphates, nitrides, and acetates, and chlorides and hydroxides, which have no adverse effect on a printed circuit board, are preferably used.

The concentration of these divalent metal ions must be 30 to 1,000 ppm. When the concentration of the divalent metal ions is lower than 30 ppm, an alkali development type solder resist has a low effect of removing development residues, consequently leaving development residues. In contrast, when the concentration is higher than 1,000 ppm, an alkali development type solder resist of which a slight amount is dissolved in wash water is flocculated to be re-bonded to, e.g., a pad portion. The preferred concentration is 50 to 1,000 ppm. When strontium ions (Sr2+) or barium ions (Ba2+) are used as a divalent metal ion, a more preferred concentration is 100 to 1,000 ppm.

The concentration of these divalent metal ions can be controlled by measurement using atomic absorption spectrophotometry, inductively-coupled plasma atomic emission spectrometry (ICPES), ion chromatography, or the like. A simplified water test kit may be also used.

Development residues can be reduced by taking such a water washing step. The probable reasons as follows.

An alkali development type solder resist with excellent flexibility and film-formation property containing a carboxyl group-containing urethane (meth)acrylate compound is difficult to dissolve and becomes an alkali metal salt when being developed in a dilute aqueous alkaline solution such as sodium carbonate. Because the alkali metal salt generates stickiness due to an action with water, no salt may be removed in a minute opening portion that is not affected by the spraying pressure of a developing machine, leaving development residues.

Washing of the alkali metal salt (usually, sodium salt) of the carboxyl group-containing (meth)acrylate compound with stickiness with water containing 30 to 1,000 ppm of divalent metal ions may result in its change to a material insoluble in water due to an exchange reaction into a divalent metal salt and to a salt bridge, and in its removal by dispersion in the wash water. In this case, a slight amount of divalent metal ions remains in the vicinity of the surface of the alkali development type solder resist layer.

Here, the divalent metal ions remaining in the vicinity of the surface of the alkali development type solder resist layer can be analyzed by, for example, a procedure described below. First, the alkali development type solder resist layer is separated by, e.g., stripping off it, and is heat-treated in, for example, pure water with an electric conductivity of 18 megaohms or higher at 100 to 120° C. for 4 to 8 hours to thermally extract ion components. The extract can be analyzed using, e.g., an ion chromatograph (model DIXION Chromatograph, made by DIONEX Corporation), to identify divalent metal ion components remaining in the vicinity of the surface of the alkali development type solder resist layer.

It is to be understood that a carboxyl group-containing urethane (meth)acrylate compound is a generic name for a carboxyl group-containing urethane acrylate resin, a carboxyl group-containing urethane methacrylate resin, and mixtures thereof, and ditto for other similar terms.

In addition, secondary washing (rinsing) is performed with ion-exchange water as needed.

The alkali development type solder resist layer washed with water (secondarily washed as needed) in such a manner is dried and then thermally cured.

In such a thermal curing step, for example, a circulating type hot-air drying oven or a far infrared ray curing oven is used to perform heating at a temperature set at, for example, about 140 to 180° C. A cured coating excellent in various properties such as heat resistance, chemical resistance, moisture absorption resistance, adhesiveness, and electrical characteristics can be formed by reaction of a thermosetting component such as an epoxy resin with a carboxyl group included in the alkali development type solder resist.

Curing may be also performed by ultraviolet irradiation before or after thermal curing in order to improve plating resistance. For example, an ultraviolet irradiation conveyor oven can be used to cure a photosensitive group such as an acrylate group unreacted and remaining after exposure. However, because there are problems such as deterioration in the adhesiveness of marking ink and a decrease in the elastic modulus of a coating, a hardening method may be appropriately chosen in consideration of purpose of use or the like.

After completing of these steps, a printed circuit board with an alkali development type solder resist layer, where an opening portion for forming, e.g., gold plating is formed in a region which will be, e.g., a pad portion in the printed circuit board, is usually formed on a substrate surface with a conductor pattern formed thereon such as copper foil.

In this case, the diameter of the opening portion is preferably 20 to 100 μm. In the case of smaller than 20 μm, it will be difficult to form an opening portion precisely due to, e.g., poor resolution during exposure. In contrast, in the case of larger than 100 μm, the size of a chip to be mounted will be so large that the merit of using CSP or UT-CSP is impaired.

It is to be understood that in the step of forming such an opening portion with a small diameter, water is difficult to flow into the opening portion, facilitating occurrence of development residues. However, the use of wash water according to the present embodiment inhibits occurrence of such development residues even in the case of forming such an opening portion with a small diameter.

The printed circuit board formed in such a manner is further degreased with, for example, an acid degreasing liquid, washed, and then immersed in a catalyst solution to apply a catalyst. Then, electroless nickel plating or electroless gold plating is performed to form a pad in an opening portion.

An alkali development type solder resist containing, for example:

(A) a carboxyl group-containing resin;
(B) a photoinitiator;
(C) a thermosetting component containing two or more cyclic ether groups and/or cyclic thioether groups in one molecule; and
(D) a diluent,
is used in an alkali development type solder resist layer formed in a method of manufacturing such a printed circuit board.

A resin compound containing a carboxylic acid in a molecule may be used as the carboxyl group-containing resin (A). In addition, a carboxyl group-containing photosensitive resin (A′) having an unsaturated ethylenic double bond in a molecule is preferably used from the viewpoint of photo-curability and development resistance.

More specifically, examples of a carboxyl group-containing resin (A) include:
(1) a carboxyl group-containing resin provided by copolymerization of an unsaturated carboxylic acid such as a (meth)acrylic acid with one or more of other compounds having an unsaturated double bond;
(2) a carboxyl group-containing resin provided by partially adding an ethylenic unsaturated group (for example, adding glycidyl methacrylate) as a pendant group to a copolymer of unsaturated carboxylic acid and any other compound having an unsaturated double bond;
(3) a carboxyl group-containing resin provided by reacting an unsaturated monocarboxylic acid with a copolymer of a compound having an epoxy group and an unsaturated double bond in one molecule, and any other compound having an unsaturated double bond, and by reacting a saturated or unsaturated polybasic acid anhydride with the generated secondary hydroxyl group;
(4) a carboxyl group-containing resin provided by reacting a polyfunctional epoxy compound with an unsaturated monocarboxylic acid, and by reacting a saturated or unsaturated polybasic acid anhydride with the generated hydroxyl group;
(5) a carboxyl group-containing resin provided by reacting a saturated or unsaturated polybasic acid anhydride with a product of reaction of a polyfunctional epoxy compound, an unsaturated monocarboxylic acid, and a compound having in one molecule at least one alcoholic hydroxyl group and one reactive group other than the alcoholic hydroxyl group, which reacts with an epoxy group;
(6) a carboxyl group-containing resin provided by reacting a polyfunctional epoxy compound with an unsaturated monocarboxylic acid, by reacting a saturated or unsaturated polybasic acid anhydride with the generated hydroxyl group, and by further reacting a compound having an epoxy group and an unsaturated double bond in one molecule such as glycidyl methacrylate;
(7) a linear carboxyl group-containing resin provided by reacting a saturated or unsaturated polybasic acid anhydride with a product of reaction of a polyfunctional bisphenol-type epoxy compound, provided by reacting an epihalohydrin with the hydroxyl group of a bifunctional bisphenol-type epoxy compound, with a unsaturated monocarboxylic acid;
(8) a linear carboxyl group-containing resin provided by alternately polymerizing a bifunctional epoxy compound such as a bisphenol-type epoxy resin, and an aromatic compound having two phenolic hydroxyl groups or a compound having two carboxyl groups, and by reacting a saturated or unsaturated polybasic acid anhydride with a product of reaction of a polyfunctional linear epoxy compound, provided by reacting an epihalohydrin with the generated hydroxyl group, and unsaturated monocarboxylic acid;
(9) a carboxyl group-containing resin provided by reacting an unsaturated group-containing monocarboxylic acid with a product of reaction of a compound having two or more phenolic hydroxyl groups in one molecule, with an alkylene oxide or cyclocarbonate compound, and by reacting a polybasic acid anhydride with the generated reaction product; and
(10) a compound provided by reacting a hydroxyl group-containing (meth)acrylate compound (a), a dimethylol alkanoic acid (b), and a diisocyanate compound (c), or a carboxyl group-containing urethane (meth)acrylate resin provided by further reacting a polymer polyol (d), (hereinafter referred to as “carboxyl group-containing urethane (meth)acrylate compound”).

Such a carboxyl group-containing resin (A) can be developed in a dilute aqueous alkaline solution because of having many free carboxyl groups in a backbone polymer side chain.

Among the above resins, the carboxyl group-containing resins (5) to (10) are, in particular, preferably used in a package substrate such as UT-CSP. Among these, inclusion of a carboxyl group-containing urethane (meth)acrylate compound (10) allows formation of a highly flexible printed circuit board more suitable for a package substrate such as UT-CSP. The included carboxyl group-containing urethane (meth)acrylate compound is preferably 35 or more parts by mass per 100 parts by mass of a carboxyl group-containing resin (A) from the viewpoint of impartation of flexibility.

Such a carboxyl group-containing resin (A) can be used singly or in combination. A carboxyl group-containing rubber-like compound such as a carboxy terminated butadiene acrylonitrile (CTBN) may be also used for imparting flexibility. From the viewpoint of impartation of flexibility, a carboxyl group-containing rubber-like compound, a linear carboxyl group-containing resin (7) or (8), or a carboxyl group-containing urethane (meth)acrylate compound (10) is preferably included in an amount of 15 to 85 mass % with respect to the total amount of the carboxyl group-containing resin (A) (15 to 85 parts by mass per 100 parts by mass of the carboxyl group-containing resin (A)).

It is to be understood that such a carboxyl group-containing urethane (meth)acrylate compound is prone to produce development residues with stickiness when developed in a dilute aqueous alkaline solution. However, the use of wash water according to the present embodiment inhibits occurrence of such development residues.

The carboxyl group-containing resin (A) preferably has an acid value ranging from 40 to 200 mgKOH/g. This is because a carboxylic acid-containing resin having an acid value of less than 40 mgKOH/g makes it difficult to perform alkali development while a resin having an acid value of more than 200 mgKOH/g too excessively promote dissolution of an exposed region by a developing solution to thin a line, or dissolve and strip off both an exposed region and an unexposed region without distinguishment by a developing solution, precluding drawing of a normal resist pattern. The more preferred acid value is in the range of 45 to 120 mgKOH/g.

The weight average molecular weight of a carboxyl group-containing resin (A) is dependent on a resin skeleton, and preferably 2,000 to 150,000 in general. A resin with a weight average molecular weight of less than 2,000 may be poor in a tack-free property, deteriorate the moisture resistance of an exposed coating, causing film reduction during development, and significantly decrease a resolution. In contrast, a resin with a weight average molecular weight exceeding 150,000 may significantly reduce developability and deteriorate storage stability. The more preferred weight average molecular weight is in the range of 5,000 to 100,000.

Such a carboxyl group-containing resin (A) preferably has a mixing rate of 20 to 60 mass % in all compositions. In the case of lower than 20 mass %, it will be difficult to obtain sufficient coating strength. In the case of higher than 60 mass %, on the other hand, viscosity is increased to deteriorate a coating property. The more preferred rate is in the range of 30 to 50 mass %.

Examples of a photoinitiator (B) include benzoin and benzoin alkyl ethers such as benzoin, benzoin methyl ether, benzoin ethyl ether, and benzoin isopropyl ether; acetophenones such as acetophenone, 2,2-dimethoxy-2-phenyl acetophenone, 2,2-diethoxy-2-phenyl acetophenone, and 1,1-dichloroacetophenone; aminoacetophenones such as 2-methyl-1-[4-(methylthio)phenyl]-2-morpholinopropane-1-on, 2-benzil-2-dimethylamino-1-(4-morpholinophenyl)-butanone-1, and 2-(dimethylamino)-2-[(4-methylphenyl)methyl]-1-[4-(4-morpholinyl)phenyl]-1-butanon; anthraquinones such as 2-methylanthraquinone, 2-ethylanthraquinone, 2-t-butylanthraquinone, and 1-chloroanthraquinone; thioxanthones such as 2,4-dimethylthioxanthone, 2,4-diethylthioxanthone, 2-chlorothioxanthone, and 2,4-diisopropylthioxanthone; ketals such as acetophenone dimethyl ketal and benzil dimethyl ketal; benzophenones such as benzil and benzophenone; or xanthones; phosphine oxides such as (2,6-dimethoxybenzoyl)-2,4,4-pentylphosphine oxide, bis(2,4,6-trimethylbenzoyl)-phenylphosphine oxide, 2,4,6-trimethylbenzoyl diphenylphosphine oxide, and ethyl-2,4,6-trimethylbenzoylphenyl phosphinate; and oxime esters such as (2-(acetyloximinomethyl)thioxanthen-9-on), (1,2-octanedione, 1-[4-(phenylthio)-, 2-(O-benzoyloxime)], and ethanone, 1-[9-ethyl-6-(2-methylbenzoyl)-9H-carbazole-3-yl]-, 1-(O-acetyloxime).

These photoinitiators (B) may be used singly or in combination. These photoinitiators (B) adequately have a mixing rate of 0.01 to 30 parts by mass per 100 parts by mass of a carboxyl group-containing resin (A). Photo-curability is deteriorated when the mixing rate of a photoinitiator (B) is smaller than 0.01 parts by mass, while a cured coating characteristic is deteriorated when the mixing rate is larger than 30 parts by mass. The mixing rate of oxime-based photoinitiators is 0.01 to 20 parts by mass, and more preferably 0.01 to 5 parts by mass.

Furthermore, a tertiary amine compound or a benzophenone compound may be contained as a photoinitiation auxiliary. Examples of such tertiary amines include ethanol amines, 4,4′-dimethylaminobenzophenone (Nissocure MABP, made by Nippon Soda Co., Ltd.), ethyl 4-dimethylaminobenzoate (Kayacure EPA, made by Nippon Kayaku Co., Ltd.), ethyl 2-dimethylaminobenzoate (Quantacure DMB, made by International Bio-Synthetics, Inc.), (n-butoxy)ethyl 4-dimethylaminobenzoate (Quantacure BEA, made by International Bio-Synthestics Company), p-dimethylamino benzoic acid isoamyl ethyl ester (Kayacure DMBI, made by Nippon Kayaku Co., Ltd.), 2-ethylhexyl 4-dimethylaminobenzoate (Esolol 507, made by Van Dyk Corporation), and 4,4′-diethylaminobenzophenone (EAB, made by Hodogaya Chemical Co., Ltd.).

These tertiary amine compounds may be used singly or in a mixed form. A particularly preferred tertiary amine compound is, but is not limited to, 4,4′-diethylaminobenzophenone. Any other compound than photoinitiators (B) or photoinitiation auxiliaries, which absorbs light in the wavelength region of 300 to 420 nm and exhibits a sensitizing effect by concurrent use of a hydrogen abstraction type photoinitiator, may be also used singly or in combination.

The thermosetting component (C) containing two or more cyclic ether groups and/or cyclic thioether groups in one molecule is used for improving a cured matter in heat resistance.

An example of the thermosetting component (C) containing two or more cyclic ether groups and/or cyclic thioether groups in one molecule, is a compound containing two or more of 3-, 4-, or 5-membered cyclic ether groups and/or cyclic thioether groups in one molecule, including a compound containing at least two or more epoxy groups in one molecule, i.e., a polyfunctional epoxy compound (C-1); a compound containing at least two or more oxetane groups in one molecule, i.e., a polyfunctional oxetane compound (C-2); and a compound containing two or more thioether groups in one molecule, i.e., a episulphide resin.

Examples of a polyfunctional epoxy compound (C-1) include, but are not limited to, bisphenol A type epoxy resins such as EPIKOTE 828, EPIKOTE 834, EPIKOTE 1001 and EPIKOTE 1004 (trade names) made by Japan Epoxy Resins Co., Ltd., EPICLON 840, EPICLON 850, EPICLON 1050 and EPICLON 2055 (trade names) made by Dainippon Ink and Chemicals Inc., Epo Tohto YD-011, YD-013, YD-127 and YD-128 (trade names) made by Tohto Kasei Co., Ltd., D.E.R.317, D.E.R.331, D.E.R.661 and D.E.R.664 (trade names) made by Dow Chemical Co., Araldide 6071, Araldide 6084, Araldide GY250 and Araldide GY260 (trade names) made by Ciba Specialty Chemicals Corp., and Sumi-epoxy ESA-011, ESA-014, ELA-115 and ELA-128 (trade names) made by Sumitomo Chemical Co., Ltd., and A.E.R.330, A.E.R.331, A.E.R.661 and A.E.R.664 (trade names) made by Asahi Kasei Corporation; brominated epoxy resins such as EPIKOTE YL903 (trade name) made by Japan Epoxy Resins Co., Ltd., EPICLON 152 and EPICLON 165 (trade names) made by Dainippon Ink and Chemicals Inc., Epo Tohto YDB-400 and YDB-500 (trade names) made by Tohto Kasei Co., Ltd., D.E.R.542 (trade name) made by Dow Chemical Co., Araldide 8011 (trade name) made by Ciba Specialty Chemicals Corp., Sumi-epoxy ESB-400 and ESB-700 (trade names) made by Sumitomo Chemical Co., Ltd., and A.E.R.711 and A.E.R.714 (trade names) made by Asahi Kasei Corporation; epoxy novolac resins such as EPIKOTE 152 and EPIKOTE 154 (trade names) made by Japan Epoxy Resins Co., Ltd., D.E.N.431 and D.E.N.438 (trade names) made by Dow Chemical Co., EPICLON N-730, EPICLON N-770 and EPICLON N-865 (trade names) made by Dainippon Ink and Chemicals Inc., Epo Tohto YDCN-701 and YDCN-704 (trade names) made by Tohto Kasei Co., Ltd., Araldide ECN1235, Araldide ECN1273, Araldide ECN1299 and Araldide XPY307 (trade names) made by Ciba Specialty Chemicals Corp., EPPN-201, EOCN-1025, EOCN-1020, EOCN-104S and RE-306 (trade names) made by Nippon Kayaku Co., Ltd., Sumi-epoxy ESCN-195× and ESCN-220 (trade names) made by Sumitomo Chemical Co., Ltd., and A.E.R.ECN-235 and ECN-299 (trade names) made by Asahi Kasei Corporation; bisphenol F type epoxy resins such as EPICLON 830 (trade name) made by Dainippon Ink and Chemicals Inc., EPIKOTE 807 (trade name) made by Japan Epoxy Resins Co., Ltd., Epo Tohto YDF-170, YDF-175 and YDF-2004 (trade names) made by Tohto Kasei Co., Ltd., and Araldide XPY306 (trade name) made by Ciba Specialty Chemicals Corp.; hydrogenated bisphenol A type epoxy resins such as Epo Tohto ST-2004, ST-2007 and ST-3000 (trade names) made by Tohto Kasei Co., Ltd.; glycidylamine type epoxy resins such as EPIKOTE 604 (trade name) made by Japan Epoxy Resins Co., Ltd., Epo Tohto YH-434 (trade name) made by Tohto Kasei Co., Ltd., Araldide MY720 (trade name) made by Ciba Specialty Chemicals Corp., and Sumi-epoxy ELM-120 (trade name) made by Sumitomo Chemical Co., Ltd.; hydantoin type epoxy resins such as Araldide CY-350 (trade name) made by Ciba Specialty Chemicals Corp.; alicyclic epoxy resins such as Celloxide 2021 (trade name) made by Daicel Chemical Industries, Ltd., and Araldide CY175 and CY179 (trade names) made by Ciba Specialty Chemicals Corp.; trihydroxyphenyl methane type epoxy resins such as YL-933 (trade name) made by Japan Epoxy Resins Co., Ltd. and T.E.N., EPPN-501 and EPPN-502 (trade names) made by Dow Chemical Co.; bixylenol type or biphenol type epoxy resins or mixtures thereof such as YL-6056, YX-4000 and YL-6121 (trade names) made by Japan Epoxy Resins Co., Ltd.; bisphenol S type epoxy resins such as EBPS-200 made by Nippon Kayaku Co., Ltd., EPX-30 made by Asahi Denka Co., Ltd., and EXA-1514 (trade name) made by Dainippon Ink and Chemicals Inc.; bisphenol A type epoxy novolac resins such as EPIKOTE 157S (trade name) made by Japan Epoxy Resins Co., Ltd.; tetraphenylol ethane type epoxy resins such as EPIKOTE YL-931 (trade name) made by Japan Epoxy Resins Co., Ltd. and Araldide 163 (trade name) made by Ciba Specialty Chemicals Corp.; heterocyclic epoxy resins such as Araldide PT810 (trade name) made by Ciba Specialty Chemicals Corp. and TEPIC (trade name) made by Nissan Chemical Industries, Ltd.; diglycidyl phthalate resins such as BLEMMER DGT made by Nippon Oil and Fats Co., Ltd.; tetraglycidyl xylenoyl ethane resins such as ZX-1063 made by Tohto Kasei Co., Ltd.; naphthalene group-containing epoxy resins such as ESN-190 and ESN-360 made by Nippon Steel Chemical Co., Ltd., and HP-4032, EXA-4750 and EXA-4700 made by Dainippon Ink and Chemicals Inc.; dicyclopentadiene skeleton-containing epoxy resins such as HP-7200 and HP-7200H made by Dainippon Ink and Chemicals Inc.; glycidyl methacrylate copolymer type epoxy resins such as CP-50S and CP-50M made by Nippon Oil and Fats Co., Ltd.; copolymeric epoxy resin of cyclohexylmaleimide and glycidyl methacrylate; epoxy modified polybutadiene rubber derivatives (e.g., PB-3600 made by Daicel Chemical Industries, Ltd.); and CTBN modified epoxy resins (e.g., YR-102 and YR-450 made by Tohto Kasei Co., Ltd.). These epoxy resins may be used singly or in combination. Among these resins, epoxy novolac resins, heterocyclic epoxy resins, bisphenol A type epoxy resins, or the mixtures thereof are preferred in particular.

Examples of a polyfunctional oxetane compound (C-2) include polyfunctional oxetanes such as bis[(3-methyl-3-oxetanylmethoxy)methyl]ether, bis[(3-ethyl-3-oxetanylmethoxy)methyl]ether, 1,4-bis[(3-methyl-3-oxetanylmethoxy)methyl]benzene, 1,4-bis[(3-ethyl-3-oxetanylmethoxy)methyl]benzene, (3-methyl-3-oxetanyl)methyl acrylate, (3-ethyl-3-oxetanyl)methyl acrylate, (3-methyl-3-oxetanyl)methyl methacrylate, (3-ethyl-3-oxetanyl)methyl methacrylate, and oligomers or copolymers thereof; and ethers of oxetane and a resin having a hydroxyl group, such as a novolac resin, poly(p-hydroxy styrene), cardo type bisphenols, calixarenes, calixresorcinarenes, and silsesquioxane. A copolymer of an unsaturated monomer having a oxetane ring, and alkyl (meth)acrylate is also included.

An example of a compound containing two or more cyclic thioether groups in one molecule is a bisphenol A type episulfide resin YL7000 made by Japan Epoxy Resins Co., Ltd. An episulfide resin or the like can be also used, in which an oxygen atom of an epoxy group of the epoxy novolac resin is replaced with a sulfur atom using a similar synthesis method.

The mixing rate of such a thermosetting component (C) containing two or more cyclic ether groups and/or cyclic thioether groups in one molecule is preferably an equivalent weight of 0.5 to 2.0 with respect to the total weight, corresponding to an equivalent weight of 1, of the carboxyl groups of the carboxyl group-containing resin (A). When the mixing rate of a thermosetting component (C) containing two or more cyclic ether groups and/or cyclic thioether groups in one molecule is an equivalent weight of less than 0.5, carboxyl groups will remain, deteriorating heat resistance, alkali resistance, and an electrical insulation property. In contrast, when the mixing rate is an equivalent weight of more than 2.0, thermosetting components (C) containing two or more cyclic ether groups and/or cyclic thioether groups in one molecule will remain, deteriorating the strength of a coating. The more preferred mixing rate is in the range of an equivalent weight of 0.8 to 1.5.

Furthermore, for the alkali development type solder resist used in the present embodiment, a diluent (D) is used for synthesis of a carboxyl group-containing resin (A), adjustment of compositions, or improvement in photo-curability. For the diluent (D), an organic solvent (D-1) or a polymerizable monomer (D-2) can be used as a nonreactive diluent or a reactive diluent, respectively.

Examples of an organic solvent (D-1) include ketones, aromatic hydrocarbons, glycol ethers, glycol ether acetates, esters, alcohols, aliphatic hydrocarbon, and petroleum based solvents. More specific examples thereof include ketones such as methyl ethyl ketone and cyclohexanone; aromatic hydrocarbons such as toluene, xylene, and tetramethyl benzene; glycol ethers such as cellosolve, methyl cellosolve, butyl cellosolve, carbitol, methyl carbitol, butyl carbitol, propylene glycolmonomethyl ether, dipropylene glycol monomethyl ether, dipropylene glycol diethyl ether, and triethylene glycol monoethyl ether; glycol ether acetates such as dipropylene glycol methyl ether acetate, propylene glycol methyl ether acetate, propylene glycol ethyl ether acetate, and propylene glycol butyl ether acetate; esters such as ethyl acetate, butyl acetate, and acetic esters of the above glycol ethers; alcohols such as ethanol, propanol, ethylene glycol, and propylene glycol; aliphatic hydrocarbons such as octane and decane; and petroleum based solvents such as petroleum ether, petroleum naphtha, hydrogenated petroleum naphtha, and solvent naphtha. Such organic solvents (D-1) are used singly or in a mixed form.

The mixing rate of these organic solvents (D-1), which is not limited in particular and can be determined in consideration of a coating property and security of the thickness of a dry film, is preferably 300 parts or less by mass per 100 parts by mass of the total weight of a carboxyl group-containing resin (A) and a carboxyl group-containing urethane (meth)acrylate compound.

Examples of a polymerizable monomer (D-2), which is a reactive diluent, include hydroxyalkyl acrylates such as 2-hydroxyethyl acrylate and 2-hydroxypropyl acrylate; mono- or di-acrylates of glycols such as ethylene glycol, methoxytetra ethylene glycol, polyethylene glycol, and propylene glycol; acrylamides such as N,N-dimethyl acrylamide, N-methylol acrylamide, and N,N-dimethylaminopropyl acrylamide; aminoalkyl acrylates such as N,N-dimethylaminoethyl acrylate and N,N-dimethylaminopropyl acrylate; polyalcohols such as hexanediol, trimethylolpropane, pentaerythritol, dipentaerythritol, and tris-hydroxyethyl isocyanurate, or polyacrylates such as ethylene oxide adducts or propylene oxide adducts thereof; acrylates such as phenoxy acrylate, bisphenol A diacrylate, and ethylene oxide adducts or propylene oxide adducts of phenols thereof; acrylates of glycidyl ethers such as glycerin diglycidyl ether, glycerin triglycidyl ether, trimethylol propane triglycidyl ether, and triglycidyl isocyanurate; melamine acrylate; and/or each of methacrylates corresponding to the above acrylates. Among these, a polyfunctional (meth)acrylate compound which contains two or more ethylenic unsaturated groups in one molecule is excellent in photo-curability and preferred in particular.

Also included are a epoxy acrylate resin provided by reacting an acrylic acid with a polyfunctional epoxy resin such as a bisphenol A, a bisphenol F type epoxy resin, and phenol and epoxy cresol novolac resins, and a epoxy urethane acrylate compound provided by reacting a half-urethane compound of a hydroxy acrylate such as a pentaerythritol triacrylate, and a diisocyanate such as a isophorone diisocyanate with the hydroxyl group of the epoxy acrylate resin. Such epoxy acrylate-based resins can improve photo-curability without deterioration of a tack-free property.

The mixing rate of such polymerizable monomers (D-2) is preferably 120 parts or less by mass per 100 parts by mass of a carboxyl group-containing resin (A). When the mixing rate of a polymerizable monomer (D-2) is more than 120 parts by mass, an electrical insulation property will be deteriorated or a coating will be fragile. The more preferred mixing rate is 10 to 70 parts by mass.

An alkali development type solder resist to be used in the present embodiment preferably contains a curing catalyst to accelerate a curing reaction of a thermosetting component (C) containing two or more cyclic ether groups and/or cyclic thioether groups in one molecule with the carboxyl groups of a carboxyl group-containing resin (A).

Examples of such a curing catalyst include imidazole derivatives such as imidazole, 2-methylimidazole, 2-ethylimidazole, 2-ethyl-4-methylimidazole, 2-phenylimidazole, 4-phenylimidazole, 1-cyanoethyl-2-phenylimidazole, and 1-(2-cyanoethyl)-2-ethyl-4-methylimidazole; amine compounds such as dicyandiamide, benzyldimethylamine, 4-(dimethylamino)-N,N-dimethylbenzylamine, 4-methoxy-N,N-dimethylbenzylamine, and 4-methyl-N,N-dimethylbenzylamine; hydrazine compounds such as hydrazide adipate and hydrazide sebacate; and phosphorus compounds such as triphenylphosphine; as well as, as commercially available products, 2MZ-A, 2MZ-OK, 2PHZ, 2P4BHZ, and 2P4MHZ (trade names of imidazole-based compounds) made by Shikoku Chemicals Corporation; U-CAT 3503N and U-CAT 3502T (trade names of block isocyanate compounds of dimethylamine) and DBU, DBN, U-CATSA102 and U-CAT5002 (bicyclic amidine compounds and the salts thereof) made by San-Apro, Ltd. Such curing catalysts are not particularly limited thereto, need only to accelerate a reaction of a carboxyl group with a heat-curing catalyst of an epoxy resin or an oxetane compound, or an epoxy group and/or an oxetanyl group, and may be used singly or in a mixed form. S-triazine derivatives which serve as an adhesiveness-imparting agent can be also used, such as guanamine, acetoguanamine, benzoguanamine, melamine, 2,4-diamino-6-methacryloyloxyethyl-s-triazine, 2-vinyl-4,6-diamino-s-triazine, 2-vinyl-4,6-diamino-S-triazine/isocyanuric acid adduct, and 2,4-diamino-6-methacryloyloxyethyl-S-triazine/isocyanuric acid adduct. Preferably, these compounds which serve as an adhesiveness-imparting agent are used concurrently with a heat-curing catalyst.

A usual quantitative ratio is sufficient for the mixing rate of a curing catalyst, and is, for example, preferably 0.1 to 20 parts by mass per 100 parts by mass of the whole resin composition. When the mixing rate of a curing catalyst is less than 0.1 parts by mass, curing time is prolonged, deteriorating operability and intensifying oxidation of, e.g., copper foil. In contrast, when the mixing rate of a curing catalyst exceeds 20 parts by mass, an electrical characteristic is deteriorated, or life for leaving a composition after temporary drying is shortened. The more preferred rate is in the range of 0.5 to 15.0 parts by mass.

An alkali development type solder resist to be used in the present embodiment may be also mixed with an inorganic filler for the purpose of improving a cured matter in characteristics such as adhesiveness, mechanical strength, and linear expansion coefficient. For example, inorganic fillers can be used, such as barium sulfate, barium titanate, silicon oxide powder, finely-powdered silicon oxide, amorphous silica, talc, clay, magnesium carbonate, calcium carbonate, aluminum oxide, aluminum hydroxide, and mica powder. The mixing rate thereof is preferably 0 to 80 mass % of a resin composition.

Such a resin can be also mixed with, as needed, coloring agents such as phthalocyanine blue, phthalocyanine green, iodine green, disazo yellow, crystal violet, titanium oxide, carbon black, and naphthalene black; thermal polymerization inhibitors such as hydroquinone, hydroquinone monomethyl ether, t-butyl catechol, pyrogallol, and phenothiazine; thickening agents such as pulverized silica, organic bentonite, and montmorillonite; antifoaming agents and/or leveling agents based on silicone, fluorine, polymer and the like; and additives such as silane coupling agents based on imidazole, thiazole, triazole and the like.

The printed circuit board formed in such a manner is suitably used as a package substrate such as CSP or UT-CSP.

CSP serves as an intermediate plate (interposer) for implementing an IC chip on a printed circuit board, and has a similar size to that of an IC chip. UT-CSP is a CSP with a reduced thickness.

Such CSP or UT-CSP is manufactured and implemented, for example, as described below.

First, alkali development type solder resist layers with an opening portion formed thereon are formed on both surfaces of a substrate with a conductor pattern formed thereon, respectively, to form a package substrate having a pad for connection to an IC chip and that for connection to a printed circuit board.

Next, an IC chip is connected to the IC chip connection surface of the package substrate using a wire bonding method or a flip-chip method. The IC chip is then fixed to the package substrate using a sealant (as needed, underfilling material).

In addition, solder balls are adhered to the printed circuit board connection surface of the package substrate to form CSP (UT-CSP).

The formed CSP (UT-CSP) is installed on the printed circuit board, and is implemented by melting the solder balls through a reflow oven and connecting them to the printed circuit board at gold-plated opening portions thereof.

### Example 1

An aspect of the present invention is described in detail referring to examples and comparative examples, but it will be appreciated that the present invention is not limited to these examples.

### <Synthesis of Carboxyl Group-Containing Resin>

Two thousand two hundred grams of an epoxy cresol novolac resin (EOCN-104S; made by Nippon Kayaku Co., Ltd.; softening point of 92° C.; epoxy equivalent of 220), 134 g of dimethylolpropionic acid, 648.5 g of acrylic acid, 4.6 g of methyl hydroquinone, 1,131 g of carbitol acetate, and 484.9 g of solvent naphtha, were mixed, heated to 90° C., and stirred to dissolve a reaction mixture. Next, the reaction solution was cooled to 60° C., mixed with 13.8 g of triphenylphosphine, heated to 100° C., and reacted for about 32 hours to obtain a reactant with an acid value of 0.5 mgKOH/g. Next, this was mixed with 364.7 g of tetrahydro phthalic anhydride, 137.5 g of carbitol acetate, and 58.8 g of solvent naphtha, heated to 95° C., reacted for about 6 hours, and cooled to obtain a carboxyl group-containing resin including a solid matter with an acid value of 40 mgKOH/g and a non-volatile matter of 65%. This reaction solution is hereinafter referred to as a varnish (A-1).

### <Synthesis of Carboxyl Group-Containing Urethane (Meth)acrylate Compound>

Into a 5-L separable flask equipped with a thermometer, a stirrer and a reflux condenser, 1,245 g of polycaprolactone diol (PLACCEL208 made by Daicel Chemical Industries, Ltd.; molecular weight of 830) as polymer polyol, 201 g of dimethylolpropionic acid as a dihydroxyl compound containing carboxyl groups, 777 g of isophorone diisocyanate as polyisocyanate, 119 g of 2-hydroxyethyl acrylate as (meth)acrylate containing hydroxyl groups were introduced, and each 0.5 g of p-methoxyphenol and di-t-butyl-hydroxytoluene were introduced. While stirring, the mixture was heated to 60° C., heating was stopped, and 0.8 g of dibutyltin dilaurate was added. When the temperature in the reaction vessel began to decrease, heating was restarted, stirring was continued at 80° C., the absorption spectrum of isocyanate groups was confirmed to disappear in an infrared absorption spectrum (2,280 cm-1) until terminating the reaction, and a urethane acrylate compound in viscous liquid form was obtained. The compound was adjusted to a non-volatile matter of 50 mass % using carbitol acetate, to obtain a carboxyl group-containing urethane (meth)acrylate compound including a solid matter with an acid value of 47 mgKOH/g and a non-volatile matter of 50%. This reaction solution is hereinafter referred to as a varnish (A-2).

### <Preparation of Alkali Development Type Solder Resist>

Using the obtained varnish (A-1) and varnish (A-2), ingredients described below were kneaded in a three-roll mill to provide an alkali development type solder resist.

Varnish (A-1): 77 parts
Varnish (A-2): 100 parts
2,4,6-Trimethylbenzoyl diphenylphosphine oxide: 10 parts
Melamine: 3 parts
Dipentaerythritol hexaacrylate: 20 parts
RE-306 (epoxy novolac resin made by Nippon Kayaku Co., Ltd.): 25 parts
Phthalocyanine green: 2 parts

### Solvent for Controlling Viscosity

Propylene glycolmonoethyl ether acetate: 10 parts

### <Production of Substrate for Evaluation>

### 1. Formation of Alkali Development Type Solder Resist Layer

An FR-4 substrate with a circuit appropriately formed thereon was buffed, entirely printed with the prepared alkali development type solder resist by screen printing, and then dried at 80° C. for 30 minutes to form a tack-free alkali development type solder resist layer.

### 2. Exposure Step

The substrate with the alkali development type solder resist layer formed thereon, and a contact exposure machine (EXP-2960 made by ORC Corporation) equipped with a high-pressure mercury-vapor lamp were beforehand used to determine an exposure value in a 6-step Kodak Step Tablet No. 2.

Then, a negative film in a predetermined pattern was put on the substrate with the alkali development type solder resist layer formed thereon, and was exposed at the determined exposure value by the above contact exposure machine.

### 3. Development Step

A 30° C., 1 mass % aqueous sodium carbonate solution was used to develop the exposed substrate by a developing machine with a spraying pressure of 0.2 MPa to form a pattern. A water washing device attached to the developing machine was held to be in a stopped state, and the substrate was taken out after the development.

4. Washing Step with Water

### (Preparation of Wash Water)

As a source of calcium ions, 2.769 mg of calcium chloride (CaCl2; molecular weight=110.98; containing calcium of 36.11 mass %) was dissolved in 1 liter of ion-exchange water to prepare wash water containing 1 ppm of calcium ions. Similarly prepared were other types of wash water containing 10, 20, 30, 100, 500, 1,000, and 10,000 ppm of calcium ions.

In addition, ion-exchange water without any calcium ion was made to be available.

(Washing with Water)

Each type of wash water and a mixing bar were put in a 2-liter beaker, and the wash water was stirred by a magnet stirrer to bring about a state with water streaming. The developed substrate for evaluation was introduced into the beaker with the wash water stirred, to wash it with the water.

Subsequently, a rinsing step was omitted, and a water content was removed with waste materials before drying.

### 5. Thermal Cure Step

The dried substrate was introduced into a circulating type hot-air drying oven, set at 150° C., for 60 minutes to cure the alkali development type solder resist layer.

In such a manner produced was the substrate for evaluation, on which the alkali development type solder resist layer with an opening portion formed thereon was formed.

### <Evaluation of Substrate>

### (1) Evaluation of Development Residues

For yet-to-be-thermally-cured substrates for evaluation with an alkali development type solder resist layer formed thereon, which was exposed and developed using a negative pattern with a drawn dot pattern for producing a dummy pad with a diameter of 80 μm, followed by being washed with each type of wash water and dried, a scanning electron microscope (SEM) was used to evaluate development residues based on the following criteria. The evaluation results are described in Table 1.

Good: Absence of any development residue and deposit.
Average: Presence of a slight amount of development residues or deposits.
Poor: Presence of development residues or deposits to cause poor adhesion of plating.

### (2) Evaluation of Heat Resistance of Solder

A substrate for evaluation with an alkali development type solder resist layer formed thereon, which was exposed and developed, followed by being washed with each type of wash water, dried, and thermally cured, was coated with a rosin-based flux and immersed in a solder tank of 260° C. for 30 seconds. The substrate was washed with propylene glycolmonomethyl ether, followed by evaluating the state of this coating based on the following criteria. The evaluation results are also described in Table 1.

Good: There is no abnormality such as a blister of a coating, a flake, or discoloration.
Poor: There is an abnormality such as a blister of a coating, a flake, or discoloration.

### (3) Evaluation of Adhesiveness of Gold Plating

A substrate for evaluation with an alkali development type solder resist layer formed thereon, which was exposed and developed, followed by being washed with each water, dried, and thermally cured, was immersed in a 30° C. acid degreasing liquid (20 vol. % aqueous solution of MetexL-5B made by Nippon MacDiarmid Co., Ltd.) for 3 minutes to be defatted, and then immersed into flowing water for 3 minutes to be washed with water. Next, the substrate was immersed in a 14.3 wt. % aqueous solution of ammon persulfate at room temperature for 3 minutes to be soft-etched, and then immersed in flowing water for 3 minutes to be washed with water. The substrate for evaluation was immersed in a 10 vol. % aqueous solution of sulfuric acid at room temperature for 1 minute, and then immersed in flowing water for 30 seconds to 1 minute to be washed with water. Furthermore, the substrate was immersed in a 30° C. catalyst solution (10 vol. % aqueous solution of Metal Plate Activator 350 made by Meltex Inc.) for 7 minutes to apply a catalyst thereto, and then immersed in flowing water for 3 minutes to be washed with water.

The substrate for evaluation to which the catalyst had been applied was immersed in a 85° C. nickel plating solution (20 vol. % aqueous solution of Melplate Ni-865M made by Meltex Inc.; pH 4.6) for 20 minutes to carry out electroless nickel plating. Next, the substrate was immersed in a 10 vol. % aqueous solution of sulfuric acid at room temperature for 1 minute, followed by being immersed in flowing water for 30 seconds to 1 minute to be washed with water. Next, the substrate was immersed in a 95° C. gold plating solution (aqueous solution of 15 vol. % Aurolectroless UP, made by Meltex Inc., and 3 vol. % potassium gold cyanide; pH 6) for 10 minutes to carry out electroless gold plating, and then immersed in flowing water for 3 minutes to be washed with water, and further immersed in 60° C. hot water for 3 minutes to be washed with hot water. After sufficient washing, water was fully drained off, and the substrate was dried to obtain an electroless-gold-plated substrate.

The obtained substrate for evaluation was observed with SEM and evaluated based on the following evaluation criteria. These evaluation results are also described in Table 1.

Good: Absence of any problem in adhesiveness of gold plating by development residues.
Poor: Presence of a problem in adhesiveness of gold plating by development residues.

### (4) Evaluation of PCT Resistance

A substrate for evaluation with a formed alkali development type solder resist layer, which was exposed and developed, followed by being washed with each type of wash water, dried, and thermally cured, was immersed in a high-temperature, high-pressure, high-humidity tank of 121° C., 2 atmospheres, and a humidity of 100% for 168 hours, and the state change of a cured coating was visually observed and evaluated based on the following criteria. The results are also described in Table 1.

Good: No remarkable blister or discoloration.
Average: Slight blister and discoloration.
Poor: Remarkable blister and discoloration.

### (5) Evaluation of Occurrence of Migration After HAST (Highly Accelerated Temperature and Humidity Stress Test)

Under an atmosphere of 130° C. and a humidity of 85%, a 5V DC was applied to a substrate for evaluation, employing an FR-4 substrate on which a comb electrode (line/space=50 μm/50 μm) was formed, with a formed alkali development type solder resist layer, which was exposed and developed, followed by being washed with each type of wash water, dried, and thermally cured, to carry out HAST for 168 hours. Subsequently, the occurrence of migration was observed with an optical microscope and was evaluated based on the following criteria. The results are also presented in Table 1.

Good: No remarkable occurrence of migration.
Average: Slight occurrence of migration.
Poor: Remarkable occurrence of migration.

### (6) Evaluation of Warpage

A substrate for evaluation, in which an insulation adhesive material with excellent thermal resistance with a thickness of 60 μm and 400 mm×300 mm (made by Hitachi Chemical Company, Ltd.) was used, with a formed alkali development type solder resist layer, which was exposed and developed, followed by being washed with each type of wash water, dried, and thermally cured, was put on a flat surface to measure the heights of the four corners of a specimen. The sum of the heights was regarded as a warpage deformation, and the warpage was evaluated using the deformation based on the following criteria. The results are also presented in Table 1.

Good: Warpage deformation of less than 20 mm.
Poor: Warpage deformation of 20 mm or more.

TABLE 1

| | Examples | | | | Comparative Examples | | | |
|---|---|---|---|---|---|---|---|---|
| | (Ca ion concentration | | | | (Ca ion concentration | | | |
| | (ppm)) | | | | (ppm)) | | | |
| | 30 | 100 | 500 | 1000 | 0 | 10 | 20 | 10000 |
| (1) Development | ◯ | ◯ | ◯ | ◯ | X | X | X | X |
| residue confirmatory | | | | | | | | |
| test | | | | | | | | |
| (2) Solder heat | ◯ | ◯ | ◯ | ◯ | ◯ | ◯ | ◯ | ◯ |
| resistance | | | | | | | | |
| (3) Adhesiveness | ◯ | ◯ | ◯ | ◯ | X | X | X | X |
| of gold plating | | | | | | | | |
| (4) PCT resistance | ◯ | ◯ | ◯ | ◯ | Δ | Δ | Δ | ◯ |
| (5) Occurrence of | ◯ | ◯ | ◯ | ◯ | Δ | Δ | Δ | ◯ |
| migration | | | | | | | | |
| (6) Evaluation of | ◯ | ◯ | ◯ | ◯ | ◯ | ◯ | ◯ | ◯ |
| warpage | | | | | | | | |

As is clear from the results presented in Table 1, the substrates washed with various types of wash water containing 30 to 1,000 ppm of calcium ions had no development residues by one wash, excellent in solder heat resistance as well as resolution, adhesiveness of gold plating, PCT resistance, and occurrence of migration, and showed no warpage.

In contrast, the substrates washed with the ion-exchange water and various types of wash waster containing 20 ppm or less of calcium ions had development residues remaining by one wash and presented problems in resolution and adhesiveness of gold plating. The substrates were also inferior in PCT resistance and occurrence of migration. The substrates washed with the water containing more than 1,000 ppm of calcium ions also had remaining development residues and presented problems in resolution and adhesiveness of gold plating. This is likely to be because alkali development type solder resists dissolved in the wash water flocculated.

### (7) Measurement of Variation in Ion Concentration in Wash Water

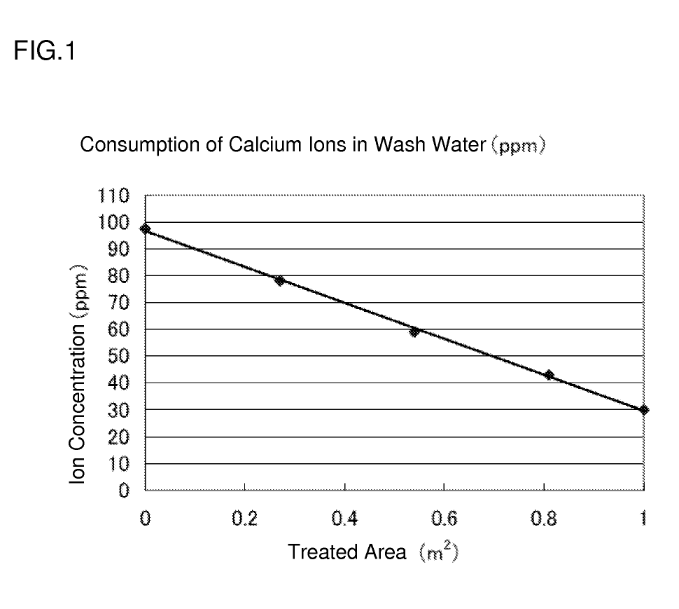

Wash water containing 100 ppm of calcium ions was used to measure variations in the treated area of a substrate and ion concentration per liter of wash water. These results are presented in FIG. 1.

As shown in FIG. 1, in the wash water containing 100 ppm of calcium ions, calcium ions decreased with increasing the treatment area, but about 30 ppm of calcium ions remained in the case of treatment of about 1 m2 per liter, and a substrate of which the area was smaller than about 1 m2 per liter was confirmed to be able to be washed without additional calcium ions without any problems. Accordingly, wash treatment with high productivity was found to be allowed.

### Example 2

A Substrate for evaluation was produced as in the case of example 1 and was washed with water containing magnesium ions substituted as divalent metal ions contained in wash water. The wash water was prepared to have a magnesium ion concentration of 50 ppm, and, in addition, waters with magnesium ion concentrations of 10 ppm and 10,000 ppm were prepared as comparative examples. Evaluations of development residues in these yet-to-be-thermally-cured substrates for evaluation, which had been dried, were carried out using SEM.

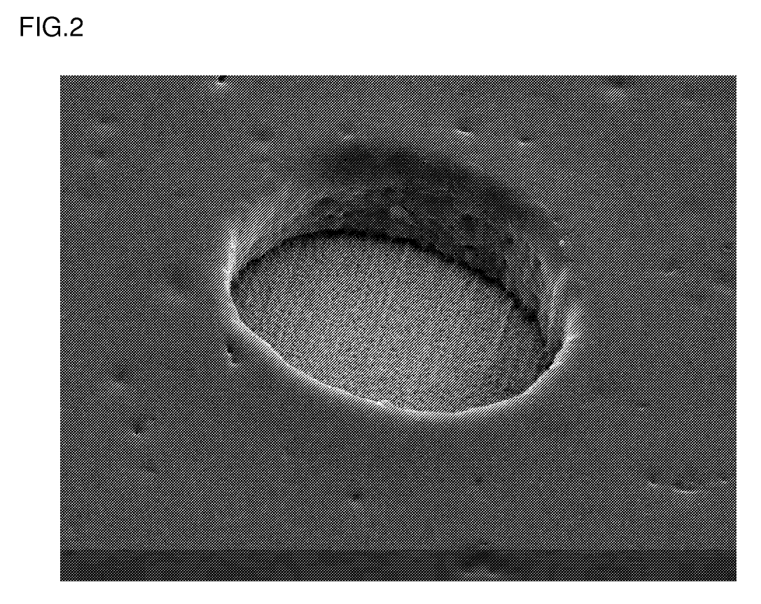

FIG. 2 shows the electron microscope photograph of a pad portion washed with wash water containing 50 ppm of magnesium ions. As shown in the figure, no development residues or the like were observed.

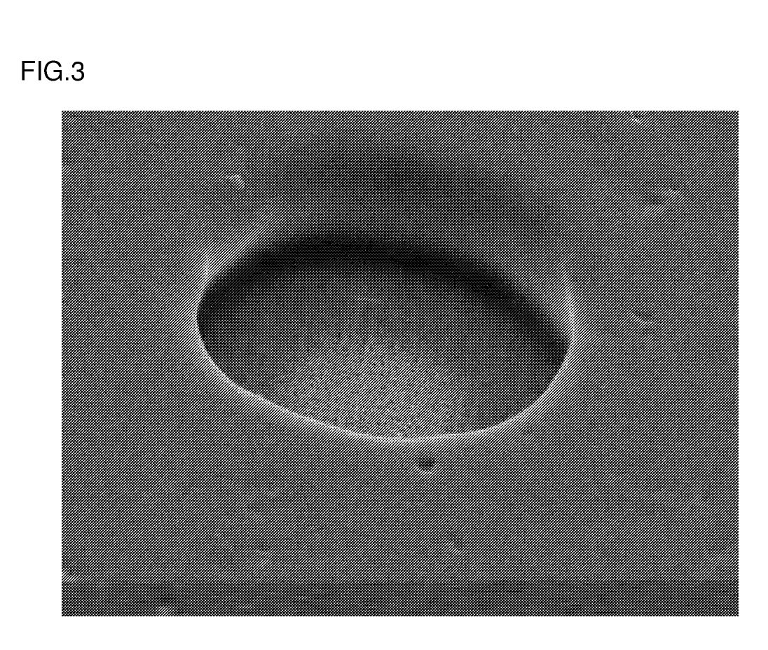

FIG. 3 shows the electron microscope photograph of a pad portion washed with wash water containing 10 ppm of magnesium ions as a comparative example. Viscous development residues were observed remaining on the periphery of a land and the outer periphery of a pad bottom.

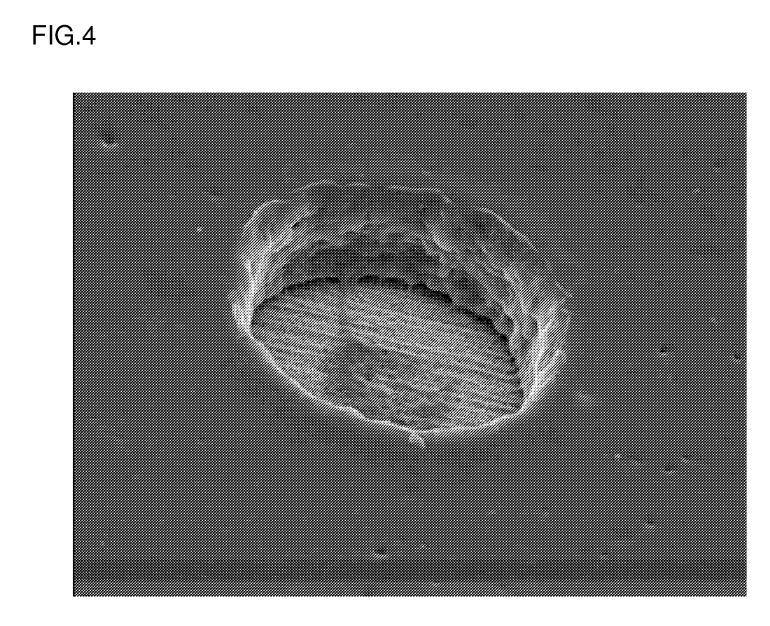

FIG. 4 shows the electron microscope photograph of a pad portion washed with wash water containing 10,000 ppm of magnesium ions as a comparative example. Resinoids were observed bonding onto a pad.

### Example 3

Alkali development type solder resists were prepared as described below to produce substrates for evaluation as in the case of example 1.

### <Synthesis of Carboxyl Group-Containing Urethane (Meth)acrylate Compound>

Into a reaction vessel equipped with a stirrer, a thermometer, and a condenser, 2,400 g (3 mol) of polycarbonate diol (PDCL800 made by Ube Industries, Ltd.; number-average molecular weight of 800) derived from 1.5-pentanediol and 1.6-hexanediol, 402 g (3 mol) of dimethylolpropionic acid as a dihydroxyl compound containing carboxyl groups, 1,554 g (7 mol) of isophorone diisocyanate as polyisocyanate, and 238 g (2.05 mol) of 2-hydroxyethyl acrylate as a monohydroxyl compound were introduced. While stirring, the mixture was heated to 60° C., heating was stopped, when the temperature in the reaction vessel began to decrease, heating was restarted, stirring was continued at 80° C., the absorption spectrum of isocyanate groups was confirmed to disappear in an infrared absorption spectrum (2,280 cm-1) until terminating the reaction, and a urethane acrylate compound in viscous liquid form was obtained. Carbitol acetate was added, so that a solid content was 50 mass %, to obtain a carboxyl group-containing urethane (meth)acrylate compound with a number-average molecular weight of 22,000 (value converted in terms of polystyrene using gel-packed liquid chromatography (GPC; GPC-1 made by Showa Denko K.K.)) and a solid content with an acid value of 46 mgKOH/g. This reaction solution is hereinafter referred to as a varnish (A-3).

### <Synthesis of Carboxyl Group-Containing Resin>

In an autoclave equipped with a thermometer, a nitrogen-introducer-cum-alkylene-oxide-introducer, and a stirrer, 119.4 parts of a cresol novolac resin (trade name “Shonol CRG951” made by Showa Highpolymer Co., Ltd.; OH equivalent of 119.4), 1.19 parts of potassium hydroxide, and 119.4 parts of toluene were mixed, nitrogen purge was performed in this system while being stirred, and heating was performed to increase a temperature. Next, 63.8 parts of propylene oxide was gradually dropped to be reacted at 125 to 132° C. at 0 to 4.8 kg/cm2 for 16 hours. Subsequently, the reaction was cooled to room temperature, 1.56 parts of 89% phosphoric acid was added and mixed to this reaction solution to neutralize potassium hydroxide, and a propylene oxide reaction solution of a cresol novolac resin with a non-volatile matter of 62.1% and a hydroxyl value of 182.2 g/eq. was obtained. An average of 1.08 mol of alkylene oxide per equivalent weight of a phenolic hydroxyl group was added to this solution.

Into a reactor equipped with a stirrer, a thermometer, and an air blowing pipe, 293.0 parts of the provided alkylene oxide reaction solution of the cresol novolac resin, 43.2 parts of acrylic acid, 11.53 parts of methanesulfonic acid, 0.18 part of methyl hydroquinone, and 252.9 parts of toluene were mixed, and air was blown at a rate of 10 mL/minute to react this at 110° C. for 12 hours while being stirred. As an azeotropic mixture with toluene, 12.6 parts of water generated by the reaction distilled. Subsequently, this was cooled to room temperature, a provided reaction solution was neutralized with 35.35 parts of a 15% aqueous sodium hydroxide solution, and then wash with water was carried out. Subsequently, toluene was removed while substituting 118.1 parts of diethylene glycol monoethyl ether acetate therewith in an evaporator, and a novolac acrylate resin solution was obtained.

Next, into the reactor equipped with the stirrer, the thermometer, and the air blowing pipe, 332.5 parts of the obtained novolac acrylate resin solution and 1.22 parts of triphenylphosphine were mixed, air was blown at a rate of 10 mL/minute, 60.8 parts of tetrahydrophthalic anhydride was gradually added while being stirred to react this at 95 to 101° C. for 6 hours, and this was taken out after cooling. A carboxyl group-containing resin with a non-volatile matter of 70.6% and a solid matter with an acid value of 87.7 mgKOH/g was obtained in such a manner. This reaction solution is hereinafter referred to as a varnish (A-4).

### <Preparation of Alkali Development Type Solder Resist>

The obtained carboxyl group-containing resin containing a carboxyl group-containing urethane (meth)acrylate compound and a novolac acrylate compound was used to knead ingredients described below in a three-roll mill to obtain an alkali development type solder resist.

Varnish (A-3): 170 parts
Varnish (A-4): 23 parts
2,4,6-Trimethylbenzoyl diphenylphosphine oxide: 10 parts
Phenothiazine: 0.2 part
Melamine: 3 parts
Dipentaerythritol hexaacrylate: 20 parts
RE-306: 25 parts
Fastogen Blue: 0.6 part
Pigment Yellow: 0.6 part
Propylene glycolmonomethyl ether acetate: 10 parts

Using the prepared alkali development type solder resist, a substrate for evaluation was produced as in the case of example 1 and was washed with wash water containing strontium ions and barium ions substituted as divalent metal ions at varied ion concentration. In addition, washing was carried out with wash water containing aluminum ions which were trivalent ions as a comparative example. Evaluations of development residues in these yet-to-be-thermally-cured substrates for evaluation, which had been dried, were carried out using SEM.

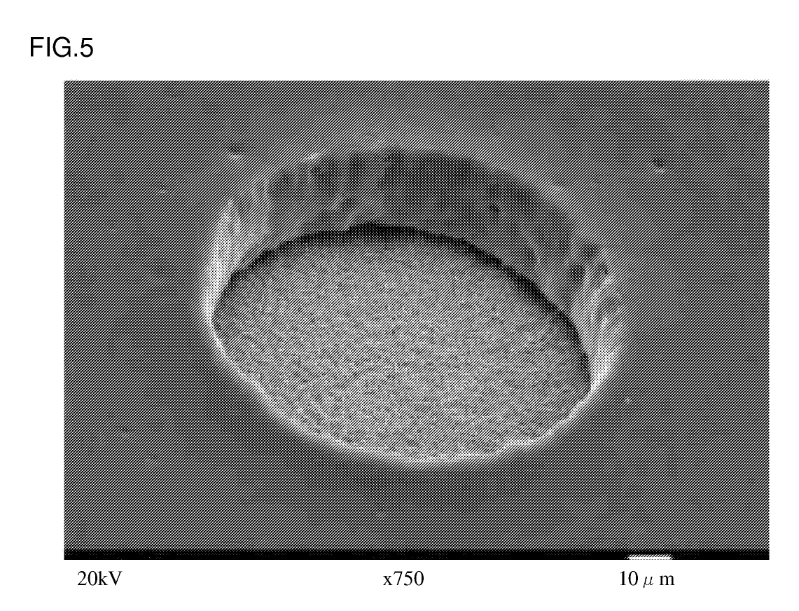

FIG. 5 shows the electron microscope photograph of a pad portion washed with wash water containing 115 ppm of strontium ions. As shown in the figure, e.g., no development residues were observed.

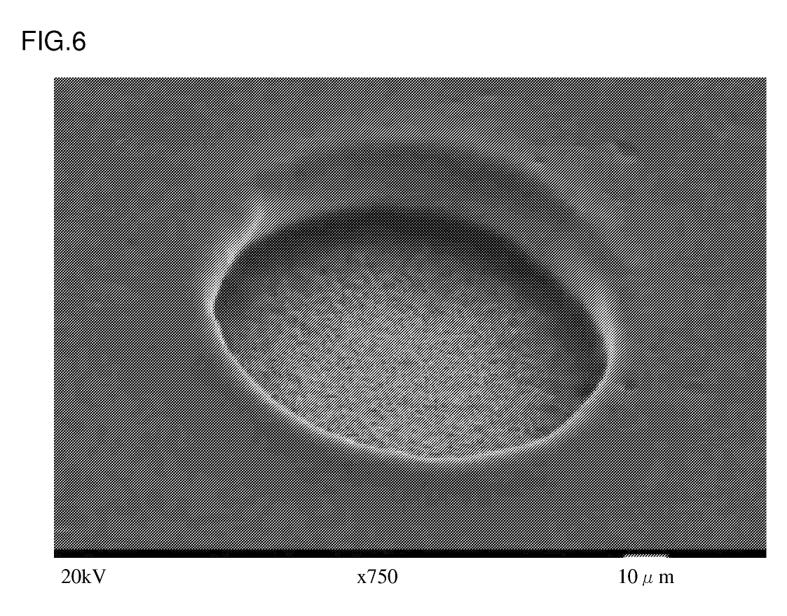

FIG. 6 shows the electron microscope photograph of a pad portion washed with wash water containing 12 ppm of strontium ions as a comparative example. Viscous development residues were observed remaining on the outer periphery of a pad bottom.

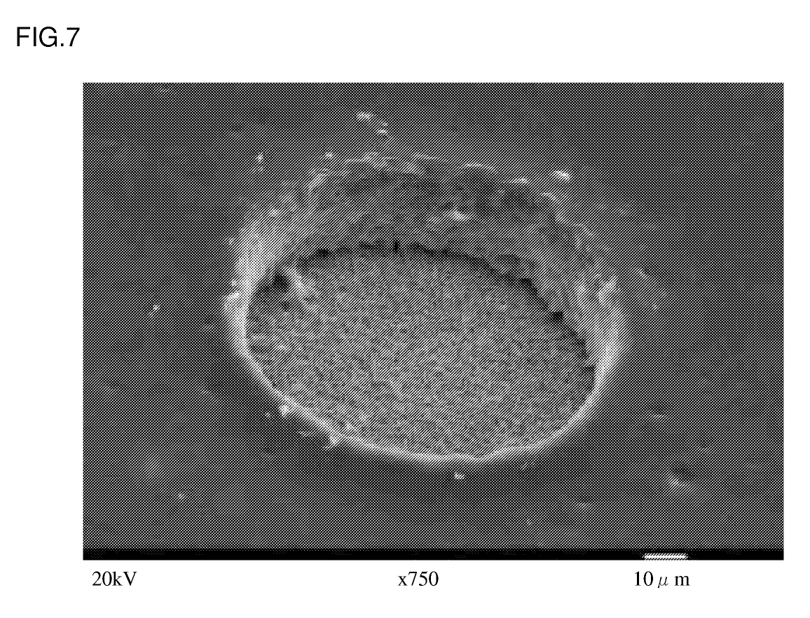

FIG. 7 shows the electron microscope photograph of a pad portion washed with wash water containing 23,000 ppm of strontium ions as a comparative example. Resinoids were observed bonding onto a pad and its periphery.

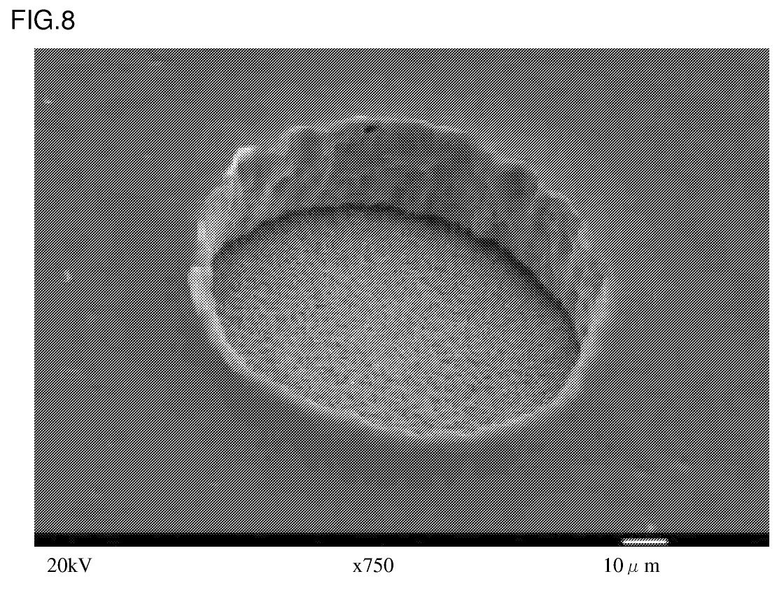

FIG. 8 shows the electron microscope photograph of a pad portion washed with wash water containing 240 ppm of barium ions. As shown in the figure, e.g., no development residues were observed.

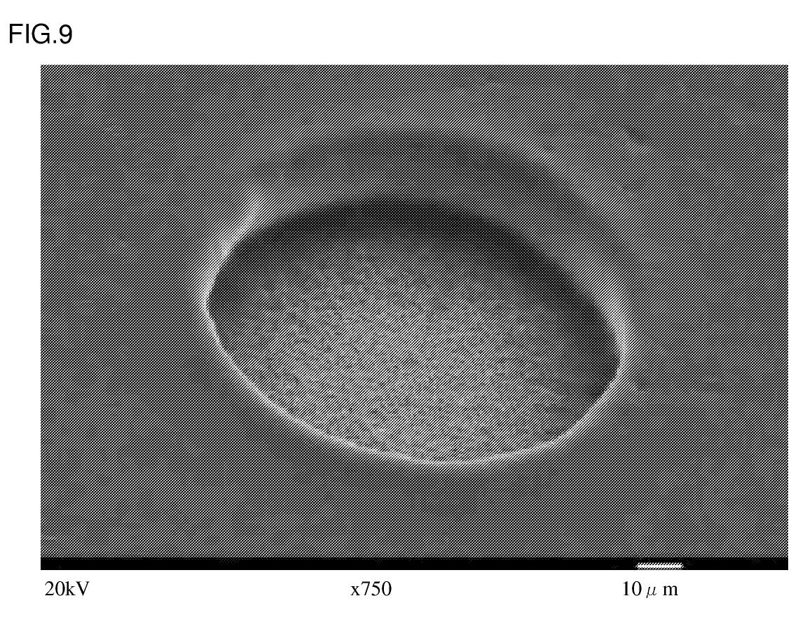

FIG. 9 shows the electron microscope photograph of a pad portion washed with wash water containing 12 ppm of barium ions as a comparative example. Viscous development residues were observed remaining on the outer periphery of a pad bottom.

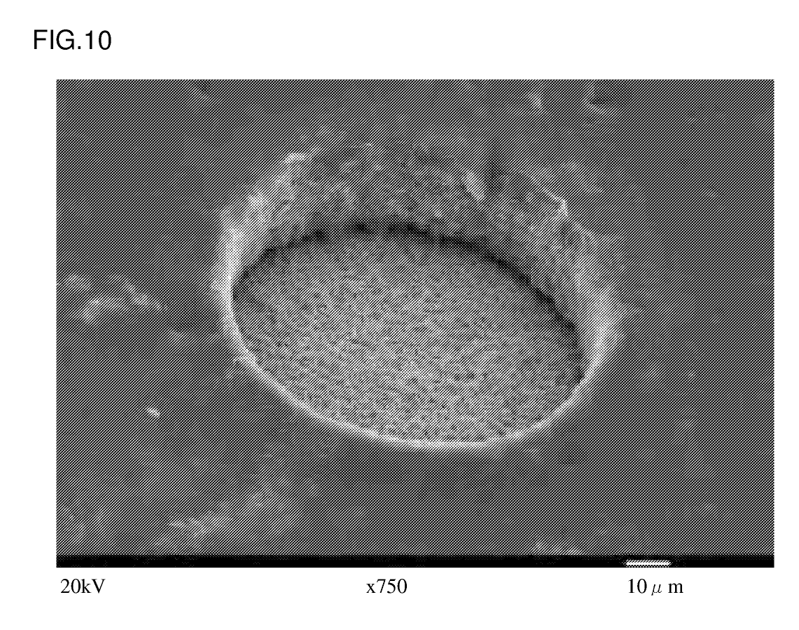

FIG. 10 shows the electron microscope photograph of a pad portion washed with wash water containing 24,000 ppm of barium ions as a comparative example. Resinoids were observed bonding onto a pad.

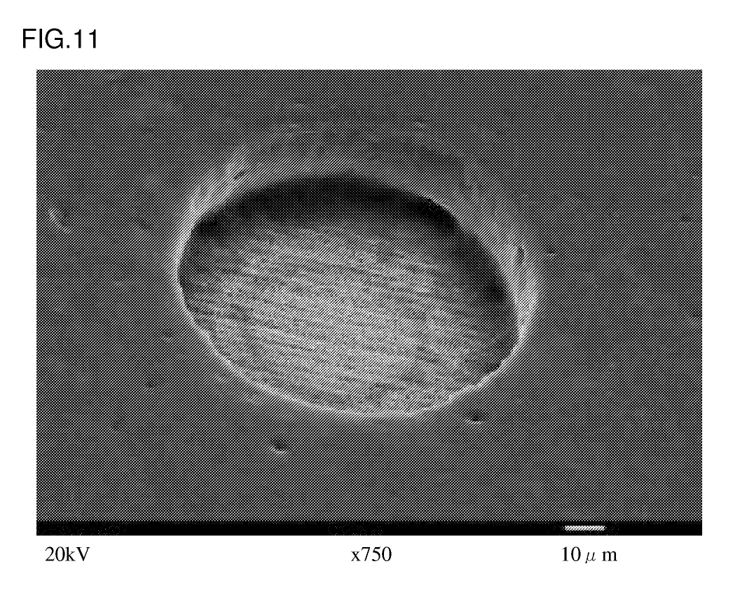

FIG. 11 shows the electron microscope photograph of a pad portion washed with wash water containing 5 ppm of trivalent aluminum ions as a comparative example. Viscous development residues were observed remaining on the outer periphery of a pad bottom. It is to be understood that a region with 5 ppm or lower allows wash with water without producing any development residue. However, it is difficult to control concentration to such a low level with high accuracy to obtain satisfactory productivity in mass production under actual conditions.

As described above, use of wash water containing 30 to 1,000 ppm of divalent metal ions in water washing after development of an alkali development type solder resist allows a reduction in, e.g., development residues in an opening portion such as a minute pad formed on the predetermined region of an alkali development type solder resist layer by one wash with the water. Accordingly, a printed circuit board capable of improving, e.g., plating adhesiveness and providing high reliability and productivity can be provided.

Obviously, numerous modifications and variations of the present invention are possible in light of the above teachings. It is therefore to be understood that within the scope of the appended claims, the invention may be practiced otherwise than as specifically described herein.

What is claimed is:

1. A method of manufacturing a printed circuit board, comprising:
forming an alkali development type solder resist layer containing a carboxyl group-containing urethane (meth)acrylate compound as a carboxyl group-containing resin on a substrate surface with a conductor pattern formed thereon; and
forming an opening portion at a predetermined position of the alkali development type solder resist layer by exposing the alkali development type solder resist layer in a predetermined opening pattern, developing the layer in a dilute aqueous alkaline solution, washing the layer with water containing 30 to 1,000 ppm of divalent metal ions, and then thermally curing the layer.

2. The method of manufacturing the printed circuit board according to claim 1, wherein the divalent metal ions are of at least one type selected from Ca²⁺, Mg²⁺, Sr²⁺, and Ba²⁺.

3. The method of manufacturing the printed circuit board according to claim 1, wherein 35 parts or more by mass of the urethane (meth)acrylate compound is included per 100 parts by mass of the carboxyl group-containing resin.

4. The method of manufacturing the printed circuit board according to claim 1, wherein the opening portion has a diameter of 20 to 100 μm.

5. The method of manufacturing the printed circuit board according to claim 1, wherein the conductor pattern includes Cu.

6. The method of manufacturing the printed circuit board according to claim 1, wherein the opening portion is formed on the conductor pattern.

7. A printed circuit board comprising:
a substrate with a conductor pattern formed thereon; and
an alkali development type solder resist layer formed on the substrate and containing a carboxyl group-containing urethane (meth)acrylate compound and divalent metal ions, in which an opening portion is formed at a predetermined position.

8. The printed circuit board according to claim 7, wherein the opening portion has a diameter of 20 to 100 μm.

9. The printed circuit board according to claim 7, wherein the conductor pattern includes Cu.

10. The printed circuit board according to claim 7, wherein the opening portion is formed on the conductor pattern.

11. The printed circuit board according to claim 7, wherein the divalent metal ions are extracted by separating the alkali development type solder resist layer and by heat treating the separated alkali development type solder resist layer in water.
